(19) United States
(12) Patent Application Publication
(10) Pub. No.: US 2007/0031596 A1
(43) Pub. Date: Feb. 8, 2007

(54) Method for reducing particle contamination in a low pressure CVD apparatus

(76) Inventors: Ch Yang, Shanghai (CN); Yi-Lung Wu, Shanghai (CN); Rey-Hsing Chiang, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/195,620

(22) Filed: Aug. 3, 2005

(51) Int. Cl. C23C 16/00

(52) U.S. Cl. 427/248.1

(57) ABSTRACT

A method for reducing particle contamination is applied in a low pressure CVD apparatus. A loading recipe is performed for setting the status of the low pressure CVD apparatus, and wherein the loading recipe comprises a first purge recipe. A processing recipe is then performed for performing a Chemical Vapor Deposition. An unloading recipe is performed for returning the status of the low pressure CVD apparatus, and wherein the unloading recipe comprises a second purge recipe. The present invention reduces the damage caused by the particles, and increase the up time of the apparatus.

### BACKGROUND OF THE INVENTION

1. Field of the Invention

The present invention relates to a method for reducing particle contamination in a low pressure CVD apparatus, and more particularly, to a method for reducing particle contamination in a low pressure CVD apparatus furnace which increases the up time and extends the time between preventive maintenance.

2. Description of the Prior Art

Chemical vapor deposition (CVD) is one common method used to form various films and layers that are used to make the components in an integrated circuit (IC). There are various types of CVD, such as low pressure (LP) CVD, high pressure (HP) CVD, plasma enhanced (PE) CVD, as well as others. CVD can be used to deposit many different types of materials, such as silicon, dielectric materials, and metals such as tungsten or titanium.

It is well known that to use a batch type plasma CVD apparatus in which a plurality of substrates is processed at the same time to form a thin film on a substrate. The batch type design is a tubular type LPCVD, which acts like a diffusion furnace and an oxidation furnace. The tubular type LPCVD is a hot wall reactor. The reactor is made of annealed quartz. Gases are admitted to the chamber from the front end of the furnace. A boat made of quartz that carries a number of wafers is then transported into the reactor and placed at a pre-determined position to perform deposition. The deposited material by the tubular type LPCVD mainly comprises polysilicon, SiO₂, and SiN. The temperature during the process is about between 400° C. and 850° C. The entire reactor of this CVD is in the react temperature. Deposition is also formed on the wall of the furnace. Therefore, the furnace must periodically be cleaned. Alternatively, if the furnace is a single wafer LPCVD, the deposition thickness on the chamber wall is less than of the tubular type LPCVD. However, these walls still need to be cleaned periodically.

In general, the cleaning step in the LPCVD reactor is performed between the continuous depositions of two wafers. After the online wafer is removed from the chamber, the cleaning step is performed. However, this process takes a lot of time to maintain the cleanliness in the chamber. Some methods use a vacancy system to process the chamber without removing the online wafer. However, a few particles in the chamber still cause the extra contamination. The cost of using the vacancy system is relatively high. Therefore, there is need for a method of cleaning the LPCVD chamber effectively.

### SUMMARY OF THE INVENTION

The present invention provides a method for reducing particle contamination, which is applied in a low pressure CVD apparatus and a purge recipe is performed in the loading/unloading recipes, which reduces the particles in the furnace.

The present invention also provides a method for increasing the up time of the furnace and extending the time between preventative maintenance, which is applied in a tubular type LPCVD apparatus. A purge recipe is not performed while the deposition is performed on the wafer, but the furnace apparatus maintains a performed cleaning and stand-by status, which increase the up time of the apparatus.

To achieve the aforementioned objects and more, a preferred embodiment of the present invention provides a method for reducing particle contamination, which is applied in a low pressure CVD apparatus. A loading recipe is performed for setting the status of the low pressure CVD apparatus, wherein the loading recipe comprises a first purge recipe. A processing recipe is then performed for performing a Chemical Vapor Deposition. An unloading recipe is performed for returning the status of the low pressure CVD apparatus, wherein the unloading recipe comprises a second purge recipe.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawing is included to provide a further understanding of the invention, and is incorporated in and constitute a part of this specification. The drawing illustrates one embodiment of the invention and, together with the description, serves to explain the principles of the invention. In the drawing,

FIG. 1 shows the flow of the low pressure CVD method according to a preferred embodiment of the present invention.

### DETAILED DESCRIPTION OF THE PREFERRED EMBODIMENTS

The present invention provides a method for reducing particle contamination, which is applied in the furnace of a low pressure CVD apparatus. Firstly, a first purge recipe is performed in the furnace in an atmospheric pressure condition. A processing recipe is then performed for performing a Chemical Vapor Deposition in the furnace. A second recipe is performed in the furnace under a vacuum condition. Therefore, the purge recipe in the processing recipe is omitted, which increases the up time of the apparatus.

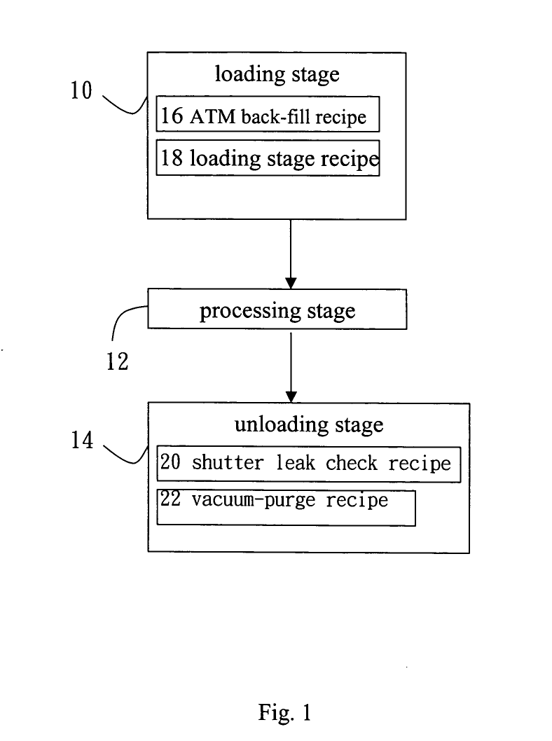

FIG. 1 shows the flow of the low pressure CVD method according to an embodiment of the present invention. In the preferred embodiment of the present invention, the flow of the LPCVD mainly comprises a loading stage 10, a processing stage 12, and an unloading stage 14. For the tubular type LPCVD apparatus, the front mount preparation in the loading stage before performing the processing stage comprises reading the environment parameter set recipe, the self-alignment and confirmation of the apparatus, and so on. The processing stage comprises positioning the boat into the furnace, moving the boat in the furnace, pre-deposition, the Chemical Vapor Deposition, the purge, and the back-fill, the boat-down, and so on. The unloading stage comprises the environment status returning, for example, the gas exhausting and the temperature cooling.

One feature of the present invention is that a first purge is performed during the loading stage. During the loading stage (also called P-charge), the required first purge recipe is called and performed. An ATM back-fill recipe 16 and the loading recipe 18 are simultaneously performed in the chamber ATM. The first purge recipe comprises three ATM back-fill and ATM check steps, wherein the ATM check steps comprise a shutter open step and the purge step. One advantage of the present invention is that a back-fill recipe and a loading recipe are simultaneously performed during the loading stage, thereby performing a first purge in the chamber before performing a processing recipe. This purge and the loading recipe are performed simultaneously without increasing the time.

Next, the deposition is performed on the wafer in the processing stage. It should be understood that a recycle purge could be performed in order to ensure the cleanliness in the chamber during the processing recipe. However, in an embodiment of the present invention, since the first purge recipe is performed in the loading stage, the purge step is reduced in the processing stage or even omitted.

When the processing stage is finished, the boat is removed from the furnace. The LPCVD apparatus performs the unloading stage. One feature of the present invention is that a second purge is performed during the unloading stage. During the unloading stage (also called P-discharge), the required second purge recipe is called, and performed. A shutter leak check recipe 20 and the vacuum-purge recipe 22 are simultaneously performed in the chamber purge. The second purge recipe comprises vacuum 1, purge 1, vacuum 2, purge 2, vacuum 3, and purge 3. One advantage of the present invention is that the second purge recipe is simultaneously performed during the unloading stage, thereby maintaining the stand-by status. Compared with the conventional method, in which three processing stages are performed with one recycle purge, the present invention increases the up time of the tubular type LPCVD apparatus by about 25%, thereby greatly extending the preventative maintenance (PM) and reducing the quantity of particle defects.

The embodiment above is only intended to illustrate the present invention; it does not, however, to limit the present invention to the specific embodiment. Accordingly, various modifications and changes may be made without departing from the spirit and scope of the present invention as described in the following claims.

What is claimed is:

1. A method for reducing particle contamination, applied in a low pressure Chemical Vapor Deposition apparatus, comprising:
performing a loading recipe for setting a status of the low pressure Chemical Vapor Deposition apparatus, wherein the loading recipe comprises performing a first purge recipe;
performing a processing recipe for performing a Chemical Vapor Deposition; and
performing an unloading recipe for returning the status of the low pressure Chemical Vapor Deposition apparatus, wherein the unloading recipe comprises performing a second purge recipe.

2. The method for reducing particle contamination of claim 1, wherein the loading recipe comprises calling an environment parameter set recipe.

3. The method for reducing particle contamination of claim 1, wherein performing the first purge recipe comprises:
performing a back-fill recipe;
opening a shutter in the low pressure Chemical Vapor Deposition apparatus; and
performing an atmospheric pressure purge recipe in the low pressure Chemical Vapor Deposition apparatus.

4. The method for reducing particle contamination of claim 1, wherein performing processing recipe comprises:
positioning a boat in a furnace in the low pressure Chemical Vapor Deposition apparatus;
performing a Vapor Deposition; and
removing the boat from the furnace in the low pressure Chemical Vapor Deposition apparatus.

5. The method for reducing particle contamination of claim 1, wherein performing the second purge recipe comprises:
performing a shutter leak check recipe in the low pressure Chemical Vapor Deposition apparatus; and
performing a vacuum-purge recipe in the low pressure Chemical Vapor Deposition apparatus.

6. A method for reducing particle contamination, applied in a furnace in a low pressure Chemical Vapor Deposition apparatus, comprising:
performing a first purge recipe in the furnace in an atmospheric pressure condition;
performing a processing recipe for performing a Chemical Vapor Deposition in the furnace; and
performing a second purge recipe in the furnace in a vacuum condition.

7. The method for reducing particle contamination of claim 6, wherein performing the first purge recipe further comprises simultaneously performing a back-fill recipe in the low pressure Chemical Vapor Deposition apparatus.

8. The method for reducing particle contamination of claim 6, wherein performing the second purge recipe further comprises simultaneously performing a leak check recipe in the low pressure Chemical Vapor Deposition apparatus.

9. The method for reducing particle contamination of claim 6, wherein performing the processing recipe comprises:
positioning a boat in the furnace;
performing a Vapor Deposition; and
removing the boat form the furnace in the low pressure Chemical Vapor Deposition apparatus.
